(19) United States
(12) Patent Application Publication
(10) Pub. No.: US 2007/0200738 A1
(43) Pub. Date: Aug. 30, 2007

(54) Efficient multiplication-free computation for signal and data processing

(76) Inventors: Yuriy Reznik, San Diego, CA (US); Hyukjune Chung, San Diego, CA (US); Harinath Garudadri, San Diego, CA (US); Naveen B. Srinivasamurthy, Mountain View, CA (US); Phoom Sagetong, San Diego, CA (US)

Correspondence Address: QUALCOMM INCORPORATED, 5775 MOREHOUSE DR., SAN DIEGO, CA, 92121, US

(21) Appl. No.: 11/545,965

(22) Filed: Oct. 10, 2006

Related U.S. Application Data
(60) Provisional application No. 60/726,307, filed on Oct. 12, 2005.
(60) Provisional application No. 60/726,702, filed on Oct. 13, 2005.

(51) Int. Cl. H03M 7/34

(52) U.S. Cl. 341/51

(57) ABSTRACT

Techniques for efficiently performing computation for signal and data processing are described. For multiplication-free processing, a series of intermediate values is generated based on an input value for data to be processed. At least one intermediate value in the series is generated based on at least one other intermediate value in the series. One intermediate value in the series is provided as an output value for a multiplication of the input value with a constant value. The constant value may be an integer constant, a rational constant, or an irrational constant. An irrational constant may be approximated with a rational dyadic constant having an integer numerator and a denominator that is a power of twos. The multiplication-free processing may be used for various transforms (e.g., DCT and IDCT), filters, and other types of signal and data processing.

### I. CLAIM OF PRIORITY UNDER 35 U.S.C. §119

The present application claims priority to provisional U.S. Application Ser. No. 60/726,307, filed Oct. 12, 2005, and provisional U.S. Application Ser. No. 60/726,702, filed Oct. 13, 2005, both entitled “Efficient Multiplication-Free Implementation of DCT (Discrete Cosine Transform)/IDCT (Inverse Discrete Cosine Transform),” assigned to the assignee hereof and incorporated herein by reference.

### BACKGROUND

II. Field

The present disclosure relates generally to processing, and more specifically to techniques for efficiently performing computation for signal and data processing.

III. Background

Signal and data processing is widely performed for various types of data in various applications. One important type of processing is transformation of data between different domains. For example, discrete cosine transform (DCT) is commonly used to transform data from spatial domain to frequency domain, and inverse discrete cosine transform (IDCT) is commonly used to transform data from frequency domain to spatial domain. DCT is widely used for image/video compression to spatially decorrelate blocks of pixels in images or video frames. The resulting transform coefficients are typically much less dependent on each other, which makes these coefficients more suitable for quantization and encoding. DCT also exhibits energy compaction property, which is the ability to map most of the energy of a block of pixels to only few (typically low order) coefficients. This energy compaction property can simplify the design of encoding algorithms.

Transforms such as DCT and IDCT, as well as other types of signal and data processing, may be performed on large quantity of data. Hence, it is desirable to perform computation for signal and data processing as efficiently as possible. Furthermore, it is desirable to perform computation using simple hardware in order to reduce cost and complexity.

There is therefore a need in the art for techniques to efficiently perform computation for signal and data processing.

### SUMMARY

Techniques for efficiently performing computation for signal and data processing are described herein. According to an embodiment of the invention, an apparatus is described which receives an input value for data to be processed and generates a series of intermediate values based on the input value. The apparatus generates at least one intermediate value in the series based on at least one other intermediate value in the series. The apparatus provides one intermediate value in the series as an output value for a multiplication of the input value with a constant value. The constant value may be an integer constant, a rational constant, or an irrational constant. An irrational constant may be approximated with a rational dyadic constant having an integer numerator and a denominator that is a power of twos.

According to another embodiment, an apparatus is described which performs processing on a set of input data values to obtain a set of output data values. The apparatus performs at least one multiplication on at least one input data value with at least one constant value for the processing. The apparatus generates at least one series of intermediate values for the at least one multiplication, with each series having at least one intermediate value generated based on at least one other intermediate value in the series. The apparatus provides one or more intermediate values in each series as one or more results of multiplication of an associated input data value with one or more constant values.

According to yet another embodiment, an apparatus is described which performs a transform on a set of input values and provides a set of output values. The apparatus performs at least one multiplication on at least one intermediate variable with at least one constant value for the transform. The apparatus generates at least one series of intermediate values for the at least one multiplication, with each series having at least one intermediate value generated based on at least one other intermediate value in the series. The apparatus provides one or more intermediate values in each series as results of multiplication of an associated intermediate variable with one or more constant values. The transform may be a DCT, an IDCT, or some other type of transform.

According to yet another embodiment, an apparatus is described which performs a transform on eight input values to obtain eight output values. The apparatus performs two multiplications on a first intermediate variable, two multiplications on a second intermediate variable, and a total of six multiplications for the transform.

Various aspects and embodiments of the invention are described in further detail below.

### BRIEF DESCRIPTION OF THE DRAWINGS

FIG. 1 shows a flow graph of an exemplary factorization of an 8-point IDCT.

FIG. 2 shows an exemplary two-dimensional IDCT.

FIG. 3 shows a flow graph of an exemplary factorization of an 8-point DCT.

FIG. 4 shows an exemplary two-dimensional DCT.

FIG. 5 shows a block diagram of an image/video coding and decoding system.

FIG. 6 shows a block diagram of an encoding system.

FIG. 7 shows a block diagram of a decoding system,

FIGS. 8A through 8C show three exemplary finite impulse response (FIR) filters.

FIG. 9 shows an exemplary infinite impulse response (IIR) filter.

### DETAILED DESCRIPTION

The word “exemplary” is used herein to mean “serving as an example, instance, or illustration.” Any exemplary embodiment described herein is not necessarily to be construed as preferred or advantageous over other exemplary embodiments.

The computation techniques described herein may be used for various types of signal and data processing such as transforms, filters, and so on. The techniques may also be used for various applications such as image and video processing, communication, computing, data networking, data storage, and so on. In general, the techniques may be used for any application that performs multiplications. For clarity, the techniques are specifically described below for DCT and IDCT, which are commonly used in image and video processing.

A one-dimensional (1D) N-point DCT and a 1D N-point IDCT of type II may be defined as follows:

$$\begin{matrix}F ( X ) = \frac{c ( X )}{2} \cdot {\sum }_{x = 0}^{N - 1} f ( x ) \cdot cos \frac{( 2 x + 1 ) \cdot X π}{2 N} , and & Eq ( 1 ) \\ F ( x ) = {\sum }_{X = 0}^{N - 1} \frac{c ( X )}{2} \cdot F ( X ) \cdot cos \frac{( 2 x + 1 ) \cdot X π}{2 N} , \\ where c ( X ) = \{ \begin{matrix}1 / \sqrt{2} & if X = 0 \\ 1 & otherwise ,\end{matrix} & Eq ( 2 )\end{matrix}$$

ƒ(x) is a 1D spatial domain function, and

F(X) is a 1D frequency domain function.

The 1D DCT in equation (1) operates on N spatial domain values for x=0, . . . , N−1 and generates N transform coefficients for X=0, . . . , N−1. The 1D IDCT in equation (2) operates on N transform coefficients and generates N spatial domain values. Type II DCT is one type of transforms and is commonly believed to be one of the most efficient transforms among several energy compacting transforms proposed for image/video compression.

A two-dimensional (2D) N×N DCT and a 2D N×N IDCT may be defined as follows:

$$\begin{matrix}F ( X , Y ) = \frac{c ( X ) \cdot c ( Y )}{4} \cdot {\sum }_{x = 0}^{N - 1} {\sum }_{y = 0}^{N - 1} f ( x , y ) \cdot cos \frac{( 2 x + 1 ) \cdot X π}{2 N} \cdot cos \frac{( 2 y + 1 ) \cdot Y π}{2 N} , and & Eq ( 3 ) \\ f ( x , y ) = {\sum }_{X = 0}^{N - 1} {\sum }_{Y = 0}^{N - 1} \frac{c ( X ) \cdot c ( Y )}{4} \cdot F ( X , Y ) \cdot cos \frac{( 2 x + 1 ) \cdot X π}{2 N} \cdot cos \frac{( 2 y + 1 ) \cdot Y π}{2 N} , \\ where c ( X ) = \{ \begin{matrix}1 / \sqrt{2} & if X = 0 \\ 1 & otherwise\end{matrix} and c ( Y ) = \{ \begin{matrix}1 / \sqrt{2} & if Y = 0 \\ 1 & otherwise ,\end{matrix} & Eq ( 4 )\end{matrix}$$

ƒ(x, y) is a 2D spatial domain function, and

F(X,Y) is a 2D frequency domain function.

The 2D DCT in equation (3) operates on an N×N block of spatial domain samples or pixels for x, y=0, . . . , N−1 and generates an N×N block of transform coefficients for X, Y=0, . . . , N−1. The 2D IDCT in equation (4) operates on an N×N block of transform coefficients and generates an N×N block of spatial domain samples. In general, 2D DCT and 2D IDCT may be performed for any block size. However, 8×8 DCT and 8×8 IDCT are commonly used for image and video processing, where N is equal to 8. For example, 8×8 DCT and 8×8 IDCT are used as standard building blocks in various image and video coding standards such as JPEG, MPEG-1, MPEG-2, MPEG-4 (P.2), H.261, H.263, and so on.

Equation (3) indicates that the 2D DCT is separable in X and Y. This separable decomposition allows a 2D DCT to be computed by first performing a 1D N-point DCT transform on each row (or each column) of an 8×8 block of data to generate an 8×8 intermediate block followed by a 1D N-point DCT on each column (or each row) of the intermediate block to generate an 8×8 block of transform coefficients. Similarly, equation (4) indicates that the 2D IDCT is separable in x and y. By decomposing the 2D DCT/IDCT into a cascade of 1D DCTs/IDCTs, the efficiency of the 2D DCT/IDCT is dependent on the efficiency of the 1D DCT/IDCT.

The 1D DCT and 1D IDCT may be implemented in their original forms shown in equations (1) and (2), respectively. However, substantial reduction in computational complexity may be realized by finding factorizations that result in as few multiplications and additions as possible.

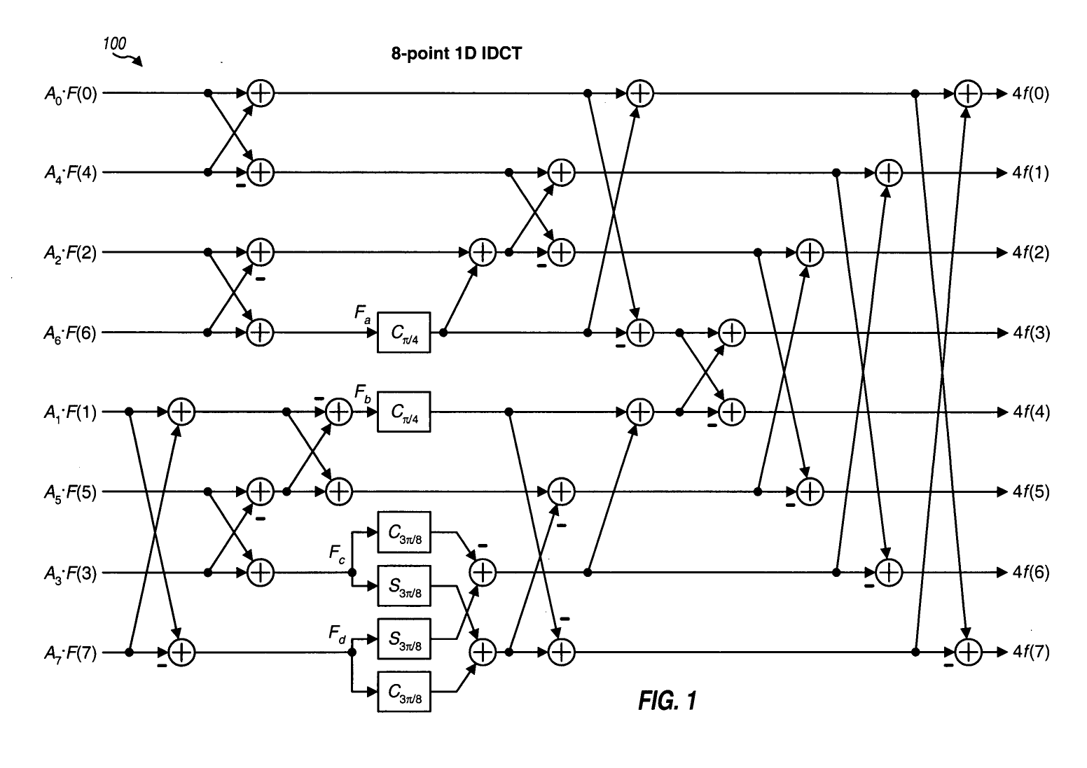

FIG. 1 shows a flow graph 100 of an exemplary factorization of an 8-point IDCT. In flow graph 100, each addition is represented by symbol “⊕” and each multiplication is represented by a box. Each addition sums or subtracts two input values and provides an output value. Each multiplication multiplies an input value with a transform constant shown inside the box and provides an output value. This factorization uses the following constant factors:
C_{π/4}=cos(π/4)≈0.707106781,
C_{3π/8}=cos(3π/8)≈0.382683432, and
S_{3π/8}=sin(3π/8)≈0.923879533.

Flow graph 100 receives eight scaled transform coefficients A₀·F(0) through A₇·F(7), performs an 8-point IDCT on these coefficients, and generates eight output samples ƒ(0) through ƒ(7). A₀ through A₇ are scale factors and are given below.

$${A}_{0} = \frac{1}{2 \sqrt{2}} \approx 0.3535533906 , \\ {A}_{1} = \frac{cos ( 7 π / 16 )}{2 sin ( 3 π / 8 ) - \sqrt{2}} \approx 0.4499881115 , \\ {A}_{2} = \frac{cos ( π / 8 )}{\sqrt{2}} \approx 0.6532814824 , \\ {A}_{3} = \frac{cos ( 5 π / 16 )}{\sqrt{2} + 2 cos ( 3 π / 8 )} \approx 0.2548977895 , \\ {A}_{4} = \frac{1}{2 \sqrt{2}} \approx 0.3535533906 , \\ {A}_{5} = \frac{cos ( 3 π / 16 )}{\sqrt{2} - 2 cos ( 3 π / 8 )} \approx 1.2814577239 , \\ {A}_{6} = \frac{cos ( 3 π / 8 )}{\sqrt{2}} \approx 0.2705980501 , \\ {A}_{7} = \frac{cos ( π / 16 )}{\sqrt{2} + 2 sin ( 3 π / 8 )} \approx 0.3006724435 .$$

Flow graph 100 includes a number of butterfly operations. A butterfly operation receives two input values and generates two output values, where one output value is the sum of the two input values and the other output value is the difference of the two input values. For example, the butterfly operation for input values A₀·F(0) and A₄·F(4) generates an output value A₀·F(0)+A₄·F(4) for the top branch and an output value A₀·F(0)−A₄·F(4) for the bottom branch.

FIG. 1 shows one exemplary factorization for an 8-point IDCT. Other factorizations have also been derived by using mappings to other known fast algorithms such as a Cooley-Tukey DFT algorithm or by applying systematic factorization procedures such as decimation in time or decimation in frequency. The factorization shown in FIG. 1 results in a total of 6 multiplications and 28 additions, which are substantially fewer than the number of multiplications and additions required for the direct computation of equation (2). In general, factorization reduces the number of essential multiplications, which are multiplications by irrational constants, but does not eliminate them.

The following terms are commonly used in mathematics:
Rational number—a ratio of two integers a/b, where b is not zero.
Irrational number—any real number that is not a rational number.
Algebraic number—any number that can be expressed as a root of a polynomial equation with integer coefficients.
Transcendental number—any real or complex number that is not rational or algebraic.

The multiplications in FIG. 1 are with irrational constants, or more specifically algebraic constants representing the sine and cosine values of different angles (multiples of π/8). These multiplications may be performed with a floating-point multiplier, which may increase cost and complexity. Alternatively, these multiplications may be efficiently performed with fixed-point integer arithmetic to achieve the desired precision using the computation techniques described herein.

In an exemplary embodiment, an irrational constant is approximated by a rational constant with a dyadic denominator, as follows:
α≈c/2^{b}, Eq (5)
where α is the irrational constant to be approximated, c and b are integers, and b>0. The fraction c/2^{b} is also commonly referred to as a dyadic fraction or a dyadic ratio. c is also referred to as a constant multiplier, and b is also referred to as a shift constant.

The approximation in equation (5) allows multiplication of an integer variable x with irrational constant α to be performed using fixed-point integer arithmetic, as follows:
x·α≈(x·c)>>b, Eq (6)
where “>>” denotes a bit-wise right shift operation, which approximates a divide by 2^{b}. The bit shift operation is similar but not exactly equal to the divide by 2^{b}.

In equation (6), the multiplication of x with α is approximated by multiplying x with integer value c and shifting the result to the right by b bits. However, there is still a multiplication of x with c. This multiplication may be acceptable for some computing environments with 1-cycle multiplications. However, it may be desirable to avoid multiplications in many environments where they take multiple cycles or large area of silicon. Examples of such existing environments include personal computers (PCs), wireless devices, cellular phones, and various embedded platforms. In these cases, the multiplication by a constant may be decomposed into a series of simpler operations, such as additions and shifts.

Performing multiplication using additions and shifts may be illustrated with an example. In this example, α=2^{-1/2}=0.7071067811. A 5-bit approximation of αwith a dyadic fraction may be given as: α⁵≈ 23/32. The binary representation of decimal 23 may be given as: 23=b010111, where “b” denoted binary. The multiplication of x with α may then be approximated as:

$$( x \cdot 23 ) / 32 \approx {\underbrace{( x >> 1 )}}_{16 x / 32} + {\underbrace{( x >> 3 )}}_{4 x / 32} + {\underbrace{( x >> 4 )}}_{2 x / 32} + \underbrace{( x >> 5 )}_{x / 32} . \qquad Eq ( 7 )$$

The multiplication in equation (7) may be achieved with four shifts and three additions. In essence, at least one operation may be performed for each ‘1’ bit in the constant multiplier c.

The same multiplication may also be performed using subtractions and shifts, as follows:

$$( x \cdot 23 ) / 32 \approx \underbrace{x}_{32 x / 32} - {\underbrace{( x >> 2 )}}_{8 x / 32} - \underbrace{( x >> 5 )}_{x / 32} . \qquad Eq ( 8 )$$

The multiplication in equation (8) may be achieved with just two shifts and two subtractions. In general, by using the above-described technique, the complexity of multiplication should be proportional to the number of ‘01’ and ‘10’ transitions in the constant multiplier c.

Equations (7) and (8) are some examples of approximating multiplication using additions and shifts. More efficient approximations may be found in some other instances.

In accordance with various exemplary embodiments, multiplications may be efficiently performed with shift and add operations and using intermediate results to reduce the total number of operations. The exemplary embodiments may be summarized as follows.

In an exemplary embodiment, multiplication by an integer constant is achieved with a series of intermediate values generated by shift and add operations. The terms “series” and “sequence” are synonymous and are used interchangeably herein. A general procedure for this exemplary embodiment may be given as follows.

Given an integer variable x and an integer constant u, an integer-valued product
z=x·u, Eq (9)
may be obtained using a series of intermediate values
z₀,z₁,z₂, . . . ,zₜ, Eq (10)
where z₀=0, z₁=x, and for all 2≦i≦t values, zᵢ is obtained as follows:
zᵢ=±zⱼ±zₖ·2^{s}^{ᵢ}, with j,k<i, Eq (11)
where “±” implies either plus or minus,

zₖ·2i implies left shift of intermediate value zₖ by sᵢ bits, and

t denotes the number of intermediate values in the series.

In equation (11), zᵢ may be equal to +zⱼ+zₖ·2^{s}^{ᵢ}, +zⱼ−zₖ·2^{s}^{ᵢ}, or −zⱼ+zₖ·2^{s}^{ᵢ}. Each intermediate value zᵢ in the series may be derived based on two prior intermediate values zⱼ and zₖ in the series, where either zⱼ or zₖ may be equal to zero. Each intermediate value zᵢ may be obtained with one shift and/or one addition. The shift is not needed if sᵢ is equal to zero. The addition is not needed if zⱼ=z₀=0. The total number of additions and shifts for the multiplication is determined by the number of intermediate values in the series, which is t, as well as the expression used for each intermediate value. The multiplication by constant u is essentially unrolled into a series of shift and add operations.

The series is defined such that the final value in the series becomes the desired integer-valued product, or
zₜ=z. Eq (12)

In another exemplary embodiment, multiplication by a rational constant with a dyadic denominator (which is also referred to as a rational dyadic constant) is approximated with a series of intermediate values generated by shift and add operations.

A general procedure for this exemplary embodiment may be given as follows.

Given an integer variable x and a rational dyadic constant u=c/2^{b}, where b and c are integers and b>0, an integer-valued product
z=(x·c)/2^{b}, Eq (13)
may be approximated using a series of intermediate values
z₀, z₁, z₂, . . . ,zₜ, Eq (14)
where z₀=0, z₁=x, and for all 2≦i ≦t values, zᵢ is obtained as follows:
zᵢ=±zⱼ±zₖ·2^{s}^{ᵢ}, with j,k<i, Eq (15)
where zₖ·2^{s}^{ᵢ} imply either left or right shift (depending on the sign of constant sᵢ) of intermediate value zₖ by |sᵢ| bits.

The series is defined such that the final value in the series becomes the desired integer-valued product, or
zₜ≈z. Eq (16)

In yet another exemplary embodiment, multiplications by multiple integer constants are achieved with a common series of intermediate values generated by shift and add operations. A general procedure for this exemplary embodiment may be given as follows.

Given an integer variable x and integer constants u and v, two integer-valued products
y=x·uand z=x·v Eq (17)
may be obtained using a series of intermediate values
w₀,w₁,w₂, . . . ,wₜ, Eq (18)
where w₀=0, w₁=x, and for all 2≦i ≦t values, wᵢ is obtained as follows:
wᵢ=±wⱼ±wₖ·2^{s}^{ᵢ}, with j,k<i, Eq (19)
where wₖ·2^{s}^{ᵢ} imply left shift of intermediate value wₖ by sᵢ bits.

The series is defined such that the desired integer-valued products are obtained at steps m and n, as follows:
wₘ=y and wₙ=z, Eq (20)

where m,n≦t and either m or n is equal to t. In still yet another exemplary embodiment, multiplications by multiple rational dyadic constants are achieved with a common series of intermediate values generated by shift and add operations. A general procedure for this exemplary embodiment may be given as follows.

Given an integer variable x and rational dyadic constants u=c/2^{b} and v=e/2^{d}, where b, c, d, e are integers, b>0 and d >0, two integer-valued products
y=(x·c)/2^{b}and z=(x·e)/2^{d} Eq (21)
may be approximated using a series of intermediate values
w₀,w₁,w₂, . . . ,wₜ, Eq (22)
where w₀=0, w₁=x, and for all 2≦i≦t values, wᵢ is obtained as follows:
wᵢ=±wⱼ±wₖ·2^{s}^{ᵢ}, with j,k<i, Eq (23)
where wₖ·2^{s}^{ᵢ} imply either left or right shift (depending on the sign of constant sᵢ) of intermediate value wₖ by |sᵢ| bits.

The series is defined such that the desired integer-valued products are obtained at steps m and n, as follows:
wₘ≈y and wₙ≈z, Eq (24)
where m, n≦t and either m or n is equal to t.

Table 1 summarizes the procedures for multiplications in accordance with the exemplary embodiments described above.

TABLE 1

| | Multiplication | Multiplication | Multiplication by | Multiplications by |
|---|---|---|---|---|
| | by integer | by irrational | multiple integer | multiple irrational |
| | constant u | constant α | constants u & v | constants α & β |
| Approximation | | α ≈ c/2^{b} | | α ≈ c/2^{b} |
| | | | | β ≈ e/2^{d} |
| Product(s) | z = x · u | z = (x · c)/2^{b} | y = x · u | y = (x · c)/2^{b} |
| | | | z = x · v | z = (x · e)/2^{d} |
| Intermediate | z₀, z₁, z₂, . . . , z₁ | z₀, z₁, z₂, . . . , zₜ | w₀, w₁, w₂, . . . , wₜ | w₀, w₁, w₂, . . . , wₜ |
| value series | | | | |
| 1^{st} value | z₀ = 0 | z₀ = 0 | w₀ = 0 | w₀ = 0 |
| 2^{nd} value | z₁ = x | z₁ = x | w₁ = x | w₁ = x |
| i-th value | zᵢ =± zⱼ ± zₖ · 2^{s}^{ᵢ} | zᵢ =± zⱼ ± zₖ · 2^{s}^{ᵢ} | wᵢ =± wⱼ ± wₖ · 2^{s}^{ᵢ} | wᵢ =± wⱼ ± wₖ · 2^{s}^{ᵢ} |
| Result(s) | z₁ = z | z₁ ≈ z | wₘ = y & wₙ = z | wₘ ≈ y & wₙ ≈ z |

Multiplications of integer variable x by one and two constants have been described above. In general, integer variable x may be multiplied by any number of constants. The multiplications of integer variable x by two or more constants may be achieved by joint factorization using a common series of intermediate values to generate desired products for the multiplications. The common series of intermediate values can take advantage of any similarities or overlaps in the computations of the multiplications in order to reduce the number of shift and add operations for these multiplications.

In the computation process for each of the exemplary embodiments described above, trivial operations such as additions and subtractions of zeros and shifts by zero bits may be omitted. The following simplifications may be made:
zᵢ±z₀±zₖ·2^{s}^{ᵢ}zᵢ=±zₖ·2^{s}^{ᵢ}, Eq (25)
wᵢ=±w₀±wₖ·2^{s}^{ᵢ}wᵢ=±wₖ·2²^{ᵢ}, Eq (26)
zᵢ=±zⱼ±zₖ·2⁰zᵢ=±zⱼ±zₖ, Eq (27)
wᵢ=±wⱼ±wₖ·2⁰wᵢ=±wⱼ±wₖ. Eq (28)

In each of equations (25) and (26), the expression to the left of [symbol] involves an addition or subtraction of zero (denoted by z₀ or w₀) and may be simplified as indicated by the corresponding expression to the right of [symbol] which may be performed with one shift.

In each of equations (27) and (28), the expression to the left of [symbol] involves a shift by zero bits (denoted by 2⁰) and may be simplified as indicated by the corresponding expression to the right of [symbol] which may be performed with one addition.

In the exemplary embodiments described above, the elements of each series are (for simplicity) referred to as “intermediate values” even though one intermediate value is equal to an input value and one or more intermediate values are equal to one or more output values. The elements of a series may also be referred to by other terminology. For example, a series may be defined to include an input value (corresponding to z₁ or w₁), zero or more intermediate results, and one or more output values (corresponding to zₜ or wₘ and wₙ).

In each of the exemplary embodiments described above, the series of intermediate values may be chosen such that the total computational or implementation cost of the entire operation is minimal. For example, the series may be chosen such that it includes the minimum number of intermediate values or the smallest t value.

The series may also be chosen such that the intermediate values can be generated with the minimum number of shift and add operations. The minimum number of intermediate values typically (but not always) results in the minimum number of operations. The desired series may be determined in various manners. In an exemplary embodiment, the desired series is determined by evaluating all possible series of intermediate values, counting the number of intermediate values or the number of operations for each series, and selecting the series with the minimum number of intermediate values and/or the minimum number of operations.

Any one of the exemplary embodiments described above may be used for one or more multiplications of integer variable x with one or more constants. The particular exemplary embodiment to use may be dependent on whether the constant(s) are integer constant(s) or irrational constant(s). Multiplications by multiple constants are common in transforms and other types of processing. In DCT and IDCT, a plane rotation is achieved by multiplications with sine and cosine. For example, intermediate variables F_{c} and F_{d} in FIG. 1 are each multiplied with both cos (3π/8) and sin (3π/8).

The multiplications in FIG. 1 may be efficiently performed using the exemplary embodiments described above. The multiplications in FIG. 1 are with the following irrational constants:
C_{π/4}=cos(π/4)≈0.707106781,
C_{3π/8}=cos(3π/8)≈0.382683432, and
S_{3π/8}=sin(3π/8)=cos(π/8)≈0.923879533.

The irrational constants above may be approximated with rational constants of sufficient number of bits to achieve the desired precision for the final results. In the following description, each transcendental constant is approximated with two rational dyadic constants. The first rational constant is selected to meet IEEE 1180-1190 precision criteria for 8-bit pixels. The second rational constant is selected to meet IEEE 1180-1190 precision criteria for 12-bit pixels.

Transcendental constant C_{π/4} may be approximated with 8-bit and 16-bit rational dyadic constants, as follows:

$${C}_{π / 4}^{8} = \frac{181}{256} = \frac{b 010110101}{b 100000000} and {C}_{π / 4}^{16} = \frac{46341}{65536} = \frac{b 01011010100000101}{b 10000000000000000} , \qquad Eq ( 29 )$$

where C_{π/4}⁸ is an 8-bit approximation of C_{π/4} and C_{π/4}¹⁶ is a 16-bit approximation of C_{π/4}.

Multiplication of integer variable x by constant C_{π/4}⁸ may be expressed as:
z=(x·181)/256. Eq (30)

The multiplication in equation (19) may be achieved with the following series of operations:

$$\begin{matrix}{z}_{1} = x , & // 1 \\ {z}_{2} = {z}_{1} + ( {z}_{1} >> 2 ) , & // 101 \\ {z}_{3} = {z}_{1} + ( {z}_{2} >> 2 ) , & // 01011 \\ {z}_{4} = {z}_{3} + ( {z}_{2} >> 6 ) , & // 010110101.\end{matrix} \qquad Eq ( 31 )$$

The binary value to the right of “//” is an intermediate constant that is multiplied with variable x.

The desired 8-bit product is equal to z₄, or z₄ =z. The multiplication in equation (30) may be performed with three additions and three shifts to generate three intermediate values z₂, z₃ and z₄.

Multiplication of integer variable x by constant C_{π/4}¹⁶ may be expressed as:
z=(x·46341)/65536. Eq(32)

The multiplication in equation (32) may be achieved with the series of intermediate values shown in equation set (31), plus one more operation:

$$\begin{matrix}{z}_{5} = {z}_{4} + ( {z}_{2} >> 11 ) , & // 01011010100000101.\end{matrix} \qquad Eq ( 33 )$$

The desired 16-bit product is approximately equal to z₅, or z₅≈z. The multiplication in equation (32) may be performed with four additions and four shifts for four intermediate values z₂, z₃, z₄ and z₅.

Constants C_{3π/8} and S_{3π/8} are used in a plane rotation in the odd part of the factorization. The odd part contains transform coefficients with odd indices. As shown in FIG. 1, multiplications by these constants are performed simultaneously for each of intermediate variables F_{c}and F_{d}. Hence, joint factorization may be used for these constants.

Transcendental constant C_{3π/8} and S_{3π/8} may be approximated with rational dyadic constants, as follows:

$$\begin{matrix}{C}_{3 π / 8}^{7} = \frac{49}{128} = \frac{b 00110001}{b 10000000} , \\ {C}_{3 π / 8}^{13} = \frac{3135}{8192} = \frac{b 00110000111111}{b 10000000000000} , and & Eq ( 34 ) \\ {S}_{3 π / 8}^{9} = \frac{473}{512} = \frac{b 0111011001}{b 1000000000} , \\ {S}_{3 π / 8}^{15} = \frac{30273}{32768} = \frac{b 0111011001000001}{b 1000000000000000} , & Eq ( 35 )\end{matrix}$$

where C_{3π/8}⁷ is a 7-bit approximation of C_{3π/8}, C_{3π/8}¹³ is a 13-bit approximation of C_{3π/8}, S_{3π/8}⁹ is a 9-bit approximation of S_{3π/8}, and S_{3π/8}¹⁵ is a 15-bit approximation of S_{3π/8}. The 7-bit approximation of C_{3π/8} and the 9-bit approximation of S_{3π/8} are sufficient to meet IEEE 1180-1190 precision criteria for 8-bit pixels. The 13-bit approximation of C_{3π/8} and the 15-bit approximation of S_{3π/8} are sufficient to achieve the desired higher precision for 16-bit pixels.

Multiplication of integer variable x by constants C_{3π/8}⁷ and S_{3π/8}⁹ may be expressed as:
y=(x·49)/128 and z=(x·473)/512. Eq(36)

The multiplications in equation (36) may be achieved with the following series of operations:

$$\begin{matrix}{w}_{1} = x , & // 1 \\ {w}_{2} = {w}_{1} - ( {w}_{1} >> 2 ) , & // 011 \\ {w}_{3} = {w}_{1} >> 6 , & // 0000001 \\ {w}_{4} = {w}_{2} + {w}_{3} , & // 0110001 \\ {w}_{5} = {w}_{1} - {w}_{3} , & // 0111111 \\ {w}_{6} = {w}_{4} >> 1 , & // 00110001 \\ {w}_{7} = {w}_{5} - ( {w}_{1} >> 4 ) , & // 0111011 \\ {w}_{8} = {w}_{7} + ( {w}_{1} >> 9 ) , & // 0111011001\end{matrix} \qquad Eq ( 37 )$$

The desired 8-bit products are equal to w₆ and w₈, or w₆=y and w₈=z. The two multiplications in equation (36) with joint factorization may be performed with five additions and five shifts to generate seven intermediate values w₂ through w₈. Additions of zeros are omitted in the generation of w₃ and w₆. Shifts by zero are omitted in the generation of w₄ and w₅.

Multiplication of integer variable x by constants C_{3π/8}¹³ and S_{3π/8}¹⁵ may be expressed as:
y=(x·3135)/8192and z=(x·30273)/32768. Eq(38)

The multiplications in equation (38) may be achieved with the following series of operations:

$$\begin{matrix}{w}_{1} = x , & // 1 \\ {w}_{2} = {w}_{1} - ( {w}_{1} >> 2 ) , & // 011 \\ {w}_{3} = {w}_{1} >> 6 , & // 0000001 \\ {w}_{4} = {w}_{1} + {w}_{3} , & // 1000001 \\ {w}_{5} = {w}_{1} - {w}_{3} , & // 0111111 \\ {w}_{6} = {w}_{2} >> 1 , & // 0011 \\ {w}_{7} = {w}_{6} + ( {w}_{5} >> 7 ) , & // 00110000111111 \\ {w}_{8} = {w}_{5} - ( {w}_{1} >> 4 ) , & // 0111011 \\ {w}_{9} = {w}_{8} + ( {w}_{4} >> 9 ) , & // 0111011001000001.\end{matrix} \qquad Eq ( 39 )$$

The desired 16-bit products are equal to w₇ and w₉, or w₇=y and w₉=z. The two multiplications in equation (38) with joint factorization may be performed with six additions and six shifts to generate eight intermediate values w₂ through w₆. Additions of zeros are omitted in the generation of w₃ and w₆. Shifts by zero are omitted in the generation of w₄ and w₅.

For the 8-point IDCT with the factorization shown in FIG. 1, using the techniques described herein for multiplications by constants C_{π/4}⁸, C_{3π/8}⁷ and S_{3π/8}⁹, the total complexity for 8-bit precision may be given as: 28+3·2+5·2=44 additions and 3·2+5·2=16 shifts. For the 8-point IDCT with multiplications by constants C_{π/4}¹⁶, C_{3π/8}¹³ and S_{3π/8}¹⁵, the total complexity for 16-bit precision may be given as: 28+4·2+6·2=48 additions and 4·2+6·2=20 shifts. In general, any desired precision may be achieved by using a sufficient number of bits for each constant. The total complexity is substantially reduced from the brute force computations shown in equation (2). Furthermore, the transform can be achieved without any multiplications and using only additions and shifts.

The sequences of intermediate values in equation sets (31), (33), (37) and (39) are exemplary sequences. The desired products may also be obtained with other sequences of intermediate values. In general, it is desirable to minimize the number of add and/or shift operations in a given sequence. On some platforms, additions may be more complex than shifts, so the goal becomes to find a sequence with minimum number of additions. On some other platforms, shifts can be more expensive, in which case, the sequence should contain minimum number of shifts (and/or total number of bits shifted in all shift operations). In general, the sequence may contain the minimum weighted average number of add and shift operations, where weights represent relative complexities of additions and shifts correspondingly. In finding such sequences, some additional constraints may also be placed. For example, it might be important to ensure that the longest sub-sequence of inter-depended intermediate values does not exceed some given value. Other example criteria that may be used in selecting the sequence may include some metrics (e.g., average value, variance, magnitude, etc.) of approximation errors introduced by right shifts.

Multiplication of an integer variable x with one or more constants may be achieved with various sequences of intermediate values. The sequence with the minimum number of add and/or shift operations, or having additional imposed constraints or optimization criteria, may be determined in various manners. In one scheme, all possible sequences of intermediate values are identified by an exhaustive search and evaluated. The sequence with the minimum number of operations (and satisfying all other constraints and criteria) is selected for use.

The sequences of intermediate values are dependent on the rational constants used to approximate the irrational constants. The shift constant b for each rational constant determines the number of bit shifts and may also influence the number of shift and add operations. A smaller shift constant usually (but not always) means fewer number of shift and add operations to approximate multiplication.

In some cases, common scale factors may be found for groups of multiplications in a flow graph such that approximation errors for the irrational constants are minimized. Such common scale factors may be combined and absorbed with the transform's input scale factors A₀ through A₇.

The 8-bit and 16-bit IDCT implementations described above were tested via computer simulations. IEEE Standard 1180-1190 and its pending replacement provide a widely accepted benchmark for accuracy of practical DCT/IDCT implementations. In summary, this standard specifies testing a reference 64-bit floating-point DCT followed by an approximate IDCT using input data from a random number generator. The reference DCT receives the input data and generates transform coefficients. The approximate IDCT receives the transform coefficients (appropriately rounded) and generates output samples. The output samples are then compared against the input data using five different metrics, which are given in Table 2. Additionally, the approximate IDCT is required to produce all zeros when supplied with zero transform coefficients and to demonstrate near-DC inversion behavior.

TABLE 2

| Metric | Description | Requirement |
|---|---|---|
| P | Maximum absolute difference between | p ≦ 1 |
| | reconstructed pixels | |
| d[x, y] | Average differences between pixels | \|d[x, y]\| ≦ 0.015 for |
| | | all [x, y] |
| M | Average of all pixel-wise differences | \|m\|≦0.0015 |
| e[x, y] | Average square difference between | \|e[x, y]\| ≦ 0.06 for |
| | pixels | all [x, y] |
| N | Average of all pixel-wise square | \|n\| ≦ 0.02 |
| | differences | |

The computer simulations indicate that IDCT employing 8-bit approximations described above satisfies the IEEE 1180-1190 precision requirements for all of the metrics in Table 2. The computer simulations further indicate that the IDCT employing 16-bit approximations described above significantly exceeds the IEEE 1180-1190 precision requirements for all of the metrics in Table 2. The 8-bit and 16-bit IDCT approximations further pass the all-zero input and near-DC inversion tests.

For clarity, much of the description above is for an efficient implementation of an 8-point scaled 1D IDCT that satisfies precision requirements of IEEE Standard 1180-1190. This scaled 1D IDCT is suitable for use in JPEG, MPEG-1,2,4, H.261, H.263 coders/decoders (codecs), and other applications. The 1D IDCT employs a scaled IDCT factorization shown in FIG. 1 with 28 additions and 6 multiplications by irrational constants. These multiplications may be unrolled into sequences of shift and add operations as described above. The number of operations is reduced by generating the sequences of intermediate values using intermediate results. Additionally, multiplications of a given variable by multiple constants are computed jointly, so that the number of shift and add operations is further reduced by computing common factors (or patterns) present in these constants only once. The overall complexity of the 8-bit 8-point scaled 1D IDCT described above is 44 additions and 16 shifts, which makes this IDCT the simplest multiplier-less IEEE-1180-compliant implementation known to date. The overall complexity of the 16-bit 8-point scaled 1D IDCT described above is 48 additions and 20 shifts. This more precise 1D IDCT may be used in MPEG-4 Studio profile and other applications and is also suitable for the new MPEG IDCT standard.

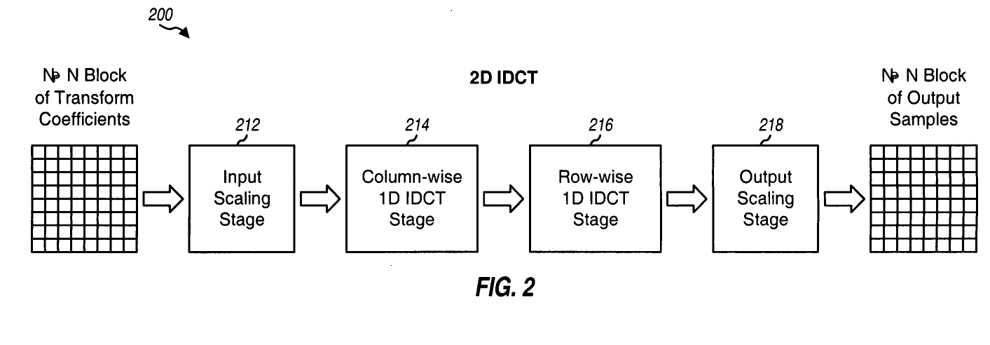

FIG. 2 shows an exemplary embodiment of a 2D IDCT 200 implemented in a scaled and separable fashion. 2D IDCT 200 comprises an input scaling stage 212, followed by a first scaled 1D IDCT stage 214 for the columns (or rows), further followed by a second scaled 1D IDCT stage 216 for the rows (or columns), and concluding with an output scaling stage 218. Scaled factorization refers to the fact that the inputs and/or outputs of the transform are multiplied by known scale factors. The scale factors may include common factors that are moved to the front and/or the back of the transform to produce simpler constants within the flow graph and thus simplify computation. Input scaling stage 212 may pre-multiply each of the transform coefficients F(X, Y) by a constant C=2^{P}, or shift each transform coefficient by P bits to the left, where P denotes the number of reserved “mantissa” bits. After the scaling, a quantity of 2^{P-1} may be added to the DC transform coefficient to achieve the proper rounding in the output samples.

First 1D IDCT stage 214 performs an N-point IDCT on each column of a block of scaled transform coefficients. Second 1D IDCT stage 216 performs an N-point IDCT on each column of an intermediate block generated by first 1D IDCT stage 214. For an 8×8 IDCT, an 8-point 1D IDCT may be performed for each column and each row as described above and shown in FIG. 1. The 1D IDCTs for the first and second stages may operate directly on their input data without doing any internal pre- or post scaling. After both the rows and columns are processed, output scaling stage 218 may shift the resulting quantities from second 1D IDCT stage 216 by P bits to the right to generate the output samples for the 2D IDCT. The scale factors and the precision constant P may be chosen such that the entire 2D IDCT may be implemented using registers of the desired width.

The scaled implementation of the 2D IDCT in FIG. 2 should result in fewer total number of multiplications and further allow a large portion of the multiplications to be executed at the quantization and/or inverse quantization stages. Quantization and inverse quantization are typically performed by an encoder. Inverse quantization is typically performed by a decoder.

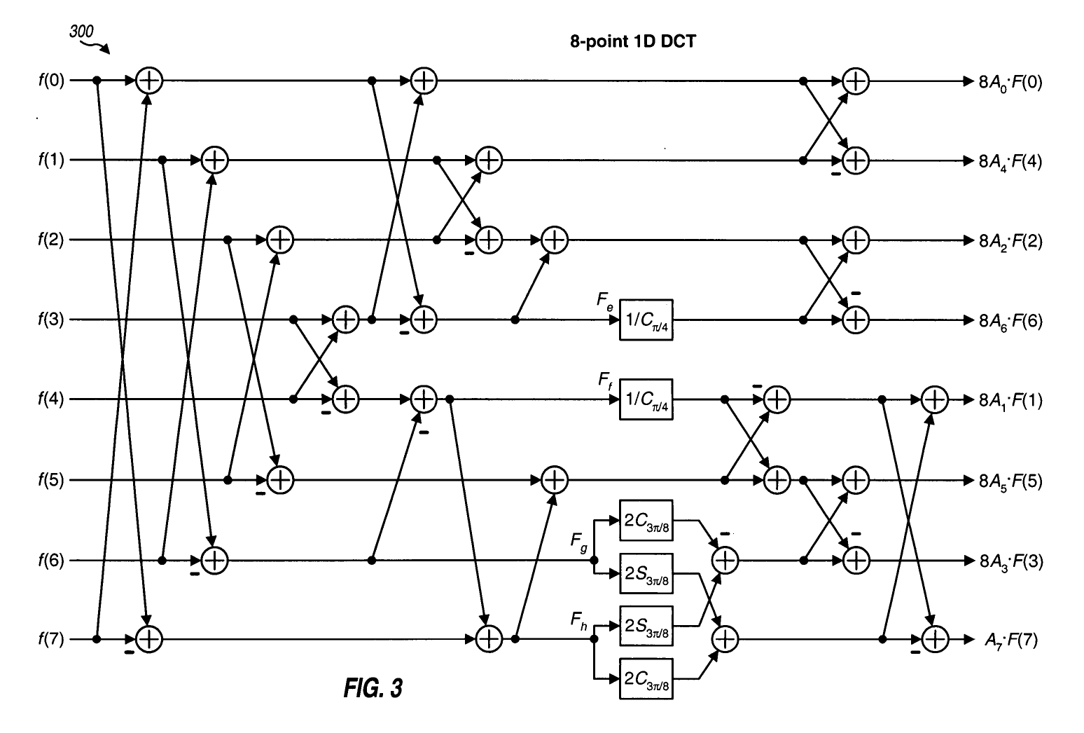

FIG. 3 shows a flow graph 300 of an exemplary factorization of an 8-point DCT. Flow graph 300 receives eight input samples ƒ(0) through ƒ(7), performs an 8-point DCT on these input samples, and generates eight scaled transform coefficients 8A₀·F(0) through 8A₇·F(7). Scale factors A₀ through A₇ are given above. Flow graph 300 is defined to use as few multiplications and additions as possible. The multiplications for intermediate variables Fₑ, F_{f}, F_{g} and Fₕ may be performed as described above. In particular, the irrational constants 1/C_{π/4}, C_{3π/8} and S_{3π/8} may be approximated with rational constants, and multiplications with the rational constants may be achieved with sequences of intermediate values.

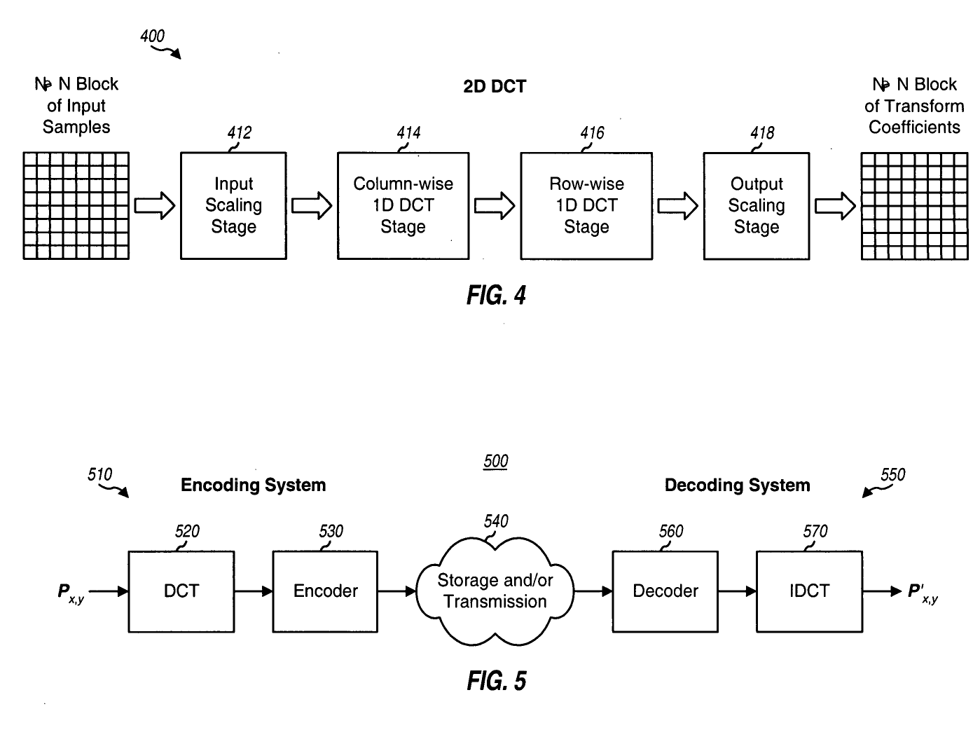

FIG. 4 shows an exemplary embodiment of a 2D DCT 400 implemented in a separable fashion and employing a scaled 1D DCT factorization. 2D DCT 400 comprises an input scaling stage 412, followed by a first 1D DCT stage 414 for the columns (or rows), followed by a second 1D DCT stage 416 for the rows (or columns), and concluding with an output scaling stage 418. Input scaling stage 412 may pre-multiply input samples. First 1D DCT stage 414 performs an N-point DCT on each column of a block of scaled transform coefficients. Second 1D DCT stage 416 performs an N-point DCT on each column of an intermediate block generated by first 1D DCT stage 414. Output scaling stage 418 may scale the output of second 1D DCT stage 416 to generate the transformed coefficients for the 2D DCT.

FIG. 5 shows a block diagram of an image/video coding and decoding system 500. At an encoding system 510, a DCT unit 520 receives an input data block (denoted as P_{x,y}) and generates a transform coefficient block. The input data block may be an N×N block of pixels, an N×N block of pixel difference values (or residue), or some other type of data generated from a source signal, e.g., a video signal. The pixel difference values may be differences between two blocks of pixels, or the differences between a block of pixels and a block of predicted pixels, and so on. N is typically equal to 8 but may also be other value. An encoder 530 receives the transform coefficient block from DCT unit 520, encodes the transform coefficients, and generates compressed data. Encoder 530 may perform various functions such as zig-zag scanning of the N×N block of transform coefficients, quantization of the transform coefficients, entropy coding, packetization, and so on. The compressed data from encoder 530 may be stored in a storage unit and/or sent via a communication channel (cloud 540).

At a decoding system 550, a decoder 560 receives the compressed data from storage unit or communication channel 540 and reconstructs the transform coefficients.

Decoder 560 may perform various functions such as de-packetization, entropy decoding, inverse quantization, inverse zig-zag scanning, and so on. An IDCT unit 570 receives the reconstructed transform coefficients from decoder 560 and generates an output data block (denoted as P′_{x,y}). The output data block may be an N×N block of reconstructed pixels, an N×N block of reconstructed pixel difference values, and so on.

The output data block is an estimate of the input data block provided to DCT unit 520 and may be used to reconstruct the source signal.

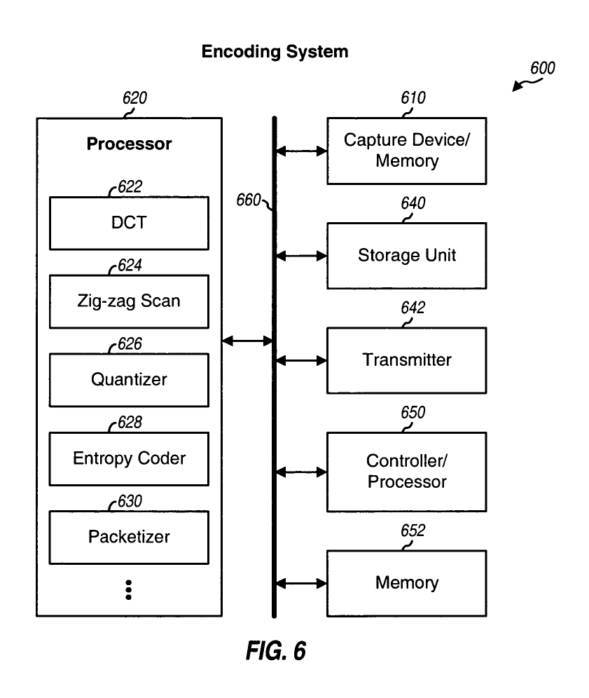

FIG. 6 shows a block diagram of an encoding system 600, which is an exemplary embodiment of encoding system 510 in FIG. 5. A capture device/memory 610 may receive a source signal, perform conversion to digital format, and provides input/raw data. Capture device 610 may be a video camera, a digitizer, or some other device. A processor 620 processes the raw data and generates compressed data. Within processor 620, the raw data may be transformed by a DCT unit 622, scanned by a zig-zag scan unit 624, quantized by a quantizer 626, encoded by an entropy encoder 628, and packetized by a packetizer 630. DCT unit 622 may perform 2DDCTs on the raw data in accordance with the techniques described above. Each of units 622 through 630 may be implemented a hardware, firmware and/or software. For example, DCT unit 622 may be implemented with dedicated hardware, or a set of instructions for an arithmetic logic unit (ALU), and so on, or a combination thereof.

A storage unit 640 may store the compressed data from processor 620. A transmitter 642 may transmit the compressed data. A controller/processor 650 controls the operation of various units in encoding system 600. A memory 652 stores data and program codes for encoding system 600. One or more buses 660 interconnect various units in encoding system 600.

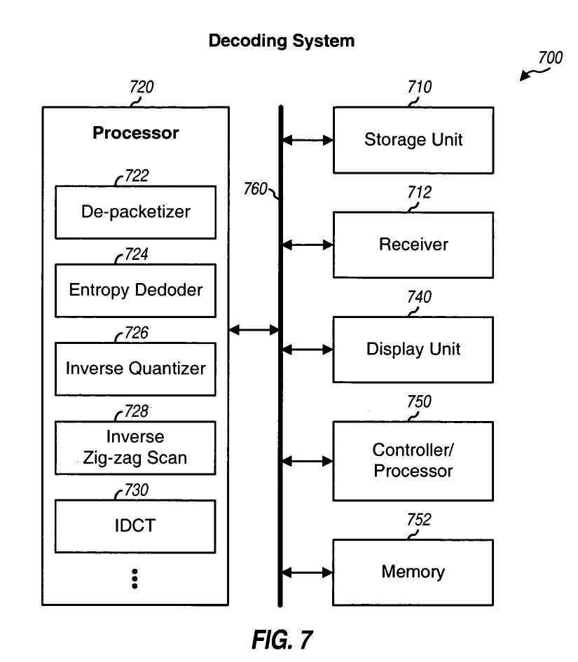

FIG. 7 shows a block diagram of a decoding system 700, which is an exemplary embodiment of decoding system 550 in FIG. 5. A receiver 710 may receive compressed data from an encoding system, and a storage unit 712 may store the received compressed data. A processor 720 processes the compressed data and generates output data. Within processor 720, the compressed data may be de-packetized by a de-packetizer 722, decoded by an entropy decoder 724, inverse quantized by an inverse quantizer 726, placed in the proper order by an inverse zig-zag scan unit 728, and transformed by an IDCT unit 730. IDCT unit 730 may perform 2D IDCTs on the reconstructed transform coefficients in accordance with the techniques described above.

Each of units 722 through 730 may be implemented a hardware, firmware and/or software. For example, FDCT unit 730 may be implemented with dedicated hardware, or a set of instructions for an ALU, and so on, or a combination thereof. A display unit 740 displays reconstructed images and video from processor 720.

A controller/processor 750 controls the operation of various units in decoding system 700. A memory 752 stores data and program codes for decoding system 700.

One or more buses 760 interconnect various units in decoding system 700.

Processors 620 and 720 may each be implemented with one or more application specific integrated circuits (ASICs), digital signal processors (DSPs), and/or some other type of processors. Alternatively, processors 620 and 720 may each be replaced with one or more random access memories (RAMs), read only memory (ROMs), electrical programmable ROMs (EPROMs), electrically erasable programmable ROMs (EEPROMs), magnetic disks, optical disks, and/or other types of volatile and nonvolatile memories known in the art.

The computation techniques described herein may be used for various types of signal and data processing. The use of the techniques for transforms has been described above. The use of the techniques for some exemplary filters is described below.

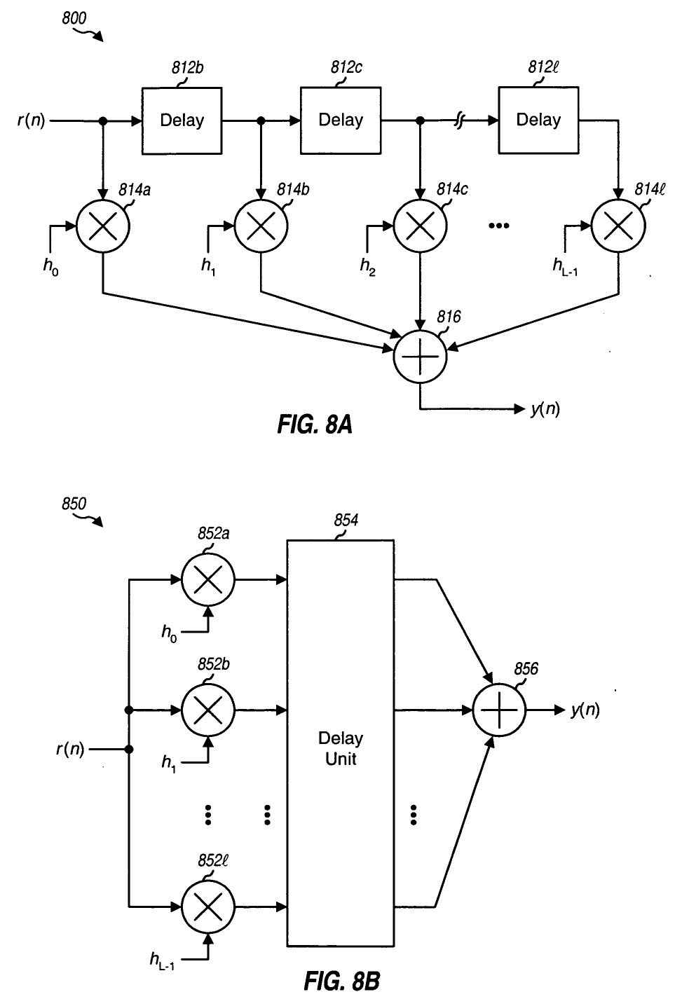

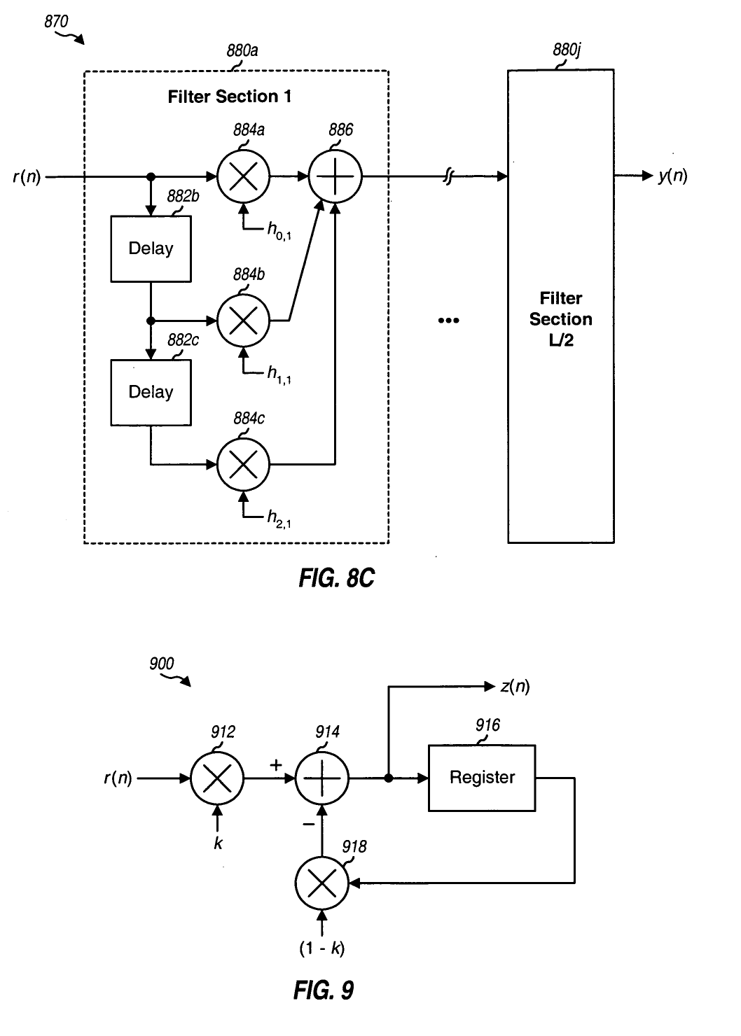

FIG. 8A shows a block diagram of an exemplary embodiment of a finite impulse response (FIR) filter 800. Within FIR filter 800, input samples r(n) are provided to a number of delay elements 812b through 812f, which are coupled in series. Each delay element 812 provides one sample period of delay. The input samples and the outputs of delay elements 812b through 812f are provided to multipliers 814a through 814f, respectively. Each multiplier 814 also receives a respective filter coefficient, multiplies its samples with the filter coefficient, and provides scaled samples to a summer 816. In each sample period, summer 816 sums the scaled samples from multipliers 814a through 814l and provides an output sample for that sample period. The output sample y(n) for sample period n may be expressed as:

$$y ( n ) = {\sum }_{i = 0}^{L - 1} {h}_{i} \cdot r ( n - i ) , \qquad Eq ( 40 )$$

where hᵢ is a filter coefficient for the i-th tap of FIR filter 800.

Each of multipliers 814a through 814l may be implemented with shift and add operations as described above. Each filter coefficient may be approximated with an integer constant or a rational dyadic constant. Each scaled sample from each multiplier 814 may be obtained based on a series of intermediate values that is generated based on the integer constant or the rational dyadic constant for that multiplier.

FIG. 8B shows a block diagram of an exemplary embodiment of a FIR filter 850. Within FIR filter 850, input samples r(n) are provided to L multipliers 852a through 852l. Each multiplier 852 also receives a respective filter coefficient, multiplies its samples with the filter coefficient, and provides scaled samples to a delay unit 854. Unit 854 delays the scaled samples for each FIR tap by an appropriate amount. In each sample period, a summer 856 sums N delayed samples from unit 854 and provides an output sample for that sample period.

FIR filter 850 also implements equation (40). However, L multiplications are performed on each input sample with L filter coefficients. Joint factorization may be used for these L multiplications to reduce the complexity of multipliers 852a through 852f.

FIG. 8C shows a block diagram of an exemplary embodiment of a FIR filter 870. FIR filter 870 includes L/2 sections 880a through 880j that are coupled in cascade. The first sections 880a receive input samples r(n), and the last section 880j provides output samples y(n). Each section 880 is a second order filter section.

Within each section 880, input samples r(n) for FIR filter 870 or output samples from a prior section are provided to delay elements 882b and 882c, which are coupled in series. The input samples and the outputs of delay elements 882b and 882c are provided to multipliers 884a through 884c, respectively. Each multiplier 884 also receives a respective filter coefficient, multiplies its samples with the filter coefficient, and provides scaled samples to a summer 886. In each sample period, summer 886 sums the scaled samples from multipliers 884a through 884c and provides an output sample for that sample period. The output sample y(n) for sample period n from the last section 880j may be expressed as:

$$y ( n ) = {\prod }_{i = 1}^{L / 2} [ {h}_{0 , i} \cdot r ( n ) + {h}_{1 , i} \cdot r ( n - 1 ) + {h}_{2 , i} \cdot r ( n - 2 ) ] , \qquad Eq ( 41 )$$

where h_{0,i}, h_{1,i} and h_{2,i} are filter coefficients for the i-th filter section.

Up to three multiplications are performed on each input sample for each section. Joint factorization may be used for these multiplications to reduce the complexity of multipliers 882a, 882b and 882c in each section.

FIG. 9 shows a block diagram of an exemplary embodiment of an infinite impulse response (IIR) filter 900. Within IIR filter 900, a multiplier 912 receives and scales input samples r(n) with a filter coefficient k and provides scaled samples. A summer 914 subtracts the output of a multiplier 918 from the scaled samples and provides output samples z(n). A register 916 stores the output samples from summer 914. Multiplier 918 multiplies the delayed output samples from register 916 with a filter coefficient (1−k) . The output sample z(n) for sample period n may be expressed as:
z(n)=k·r(n)−(1−k)·z(n−1), Eq (42)
where k is a filter coefficient that determines the amount of filtering.

Each of multipliers 912 and 918 may be implemented with shift and add operations as described above. Filter coefficient k and (1−k) may each be approximated with an integer constant or a rational dyadic constant. Each scaled sample from each of multipliers 912 and 918 may be derived based on a series of intermediate values that is generated based on the integer constant or the rational dyadic constant for that multiplier.

The computation described herein may be implemented in hardware, firmware, software, or a combination thereof. For example, the shift and add operations for a multiplication of an input value with a constant value may be implemented with one or more logic, which may also be referred to as units, modules, etc. A logic may be hardware logic comprising logic gates, transistors, and/or other circuits known in the art.

A logic may also be firmware and/or software logic comprising machine-readable codes.

In one design, an apparatus comprises (a) a first logic to receive an input value for data to be processed, (b) a second logic to generate a series of intermediate values based on the input value and to generate at least one intermediate value in the series based on at least one other intermediate value in the series, and (c) a third logic to provide one intermediate value in the series as an output value for a multiplication of the input value with a constant value. The first, second, and third logic may be separate logic. Alternatively, the first, second, and third logic may be the same common logic or shared logic. For example, the third logic may be part of the second logic, which may be part of the first logic.

An apparatus may also perform an operation on an input value by generating a series of intermediate values based on the input value, generating at least one intermediate value in the series based on at least one other intermediate value in the series, and providing one intermediate value in the series as an output value for the operation. The operation may be an arithmetic operation, a mathematical operation (e.g., multiplication), some other type of operation, or a set or combination of operations.

For a firmware and/or software implementation, a multiplication of an input value with a constant value may be achieved with machine-readable codes that perform the desired shift and add operations. The codes may be hardwired or stored in a memory (e.g., memory 652 in FIG. 6 or 752 in FIG. 7) and executed by a processor (e.g., processor 650 or 750) or some other hardware unit.

The computation techniques described herein may be implemented in various types of apparatus. For example, the techniques may be implemented in different types of processors, different types if integrated circuits, different types of electronics devices, different types of electronics circuits, and so on.

The computation techniques described herein may be implemented with hardware, firmware, software, or a combination thereof. The computation may be coded as computer-readable instructions carried on any computer-readable medium known in the art. In this specification and the appended claims, the term “computer-readable medium” refers to any medium that participates in providing instructions to any processor, such as the controllers/processors shown in FIGS. 6 and 7, for execution. Such a medium may be of a storage type and may take the form of a volatile or non-volatile storage medium as described above, for example, in the description of processors 620 and 720 in FIGS. 6 and 7, respectively. Such a medium can also be of the transmission type and may include a coaxial cable, a copper wire, an optical cable, and the air interface carrying acoustic or electromagnetic waves capable of carrying signals readable by machines or computers.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general-purpose processor, a DSP, an ASIC, a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. An apparatus comprising:
a first logic to receive an input value for data to be processed;
a second logic to generate a series of intermediate values based on the input value and to generate at least one intermediate value in the series based on at least one other intermediate value in the series; and
a third logic to provide one intermediate value in the series as an output value for a multiplication of the input value with a constant value.

2. The apparatus of claim 1, wherein the second logic generates each intermediate value in the series, except for a first intermediate value in the series, based on at least one prior intermediate value in the series.

3. The apparatus of claim 1, wherein the second logic sets a first intermediate value in the series to the input value and generates each subsequent intermediate value based on at least one prior intermediate value in the series, and wherein the third logic provides a last intermediate value in the series as the output value.

4. The apparatus of claim 1, wherein the second logic generates each intermediate value in the series, except for a first intermediate value in the series, by performing a bit shift, an addition, or a bit shift and an addition on at least one prior intermediate value in the series.

5. The apparatus of claim 1, wherein the constant value is approximated with an integer value.

6. The apparatus of claim 1, wherein the constant value is approximated with a rational dyadic constant having an integer numerator and a denominator that is a power of twos.

7. The apparatus of claim 1, wherein the third logic provides another intermediate value in the series as another output value for another multiplication of the input value with another constant value.

8. The apparatus of claim 7, wherein the constant values are approximated with integer values.

9. The apparatus of claim 7, wherein the constant values are approximated with rational dyadic constants each having an integer numerator and a denominator that is a power of twos.

10. The apparatus of claim 1, wherein the series includes a minimum number of intermediate values to obtain the output value.

11. The apparatus of claim 1, wherein the series of intermediate values is generated with a minimum number of shift and add operations.

12. A method comprising:
receiving an input value for data to be processed;
generating a series of intermediate values based on the input value, at least one intermediate value in the series being generated based on at least one other intermediate value in the series; and
providing one intermediate value in the series as an output value for a multiplication of the input value with a constant value.

13. The method of claim 12, wherein the generating the series of intermediate values comprises
setting a first intermediate value in the series to the input value, and
generating each subsequent intermediate value based on at least one prior intermediate value in the series.

14. The method of claim 12, wherein the generating the series of intermediate values comprises
generating each intermediate value in the series, except for a first intermediate value in the series, by performing a bit shift, an addition, or a bit shift and an addition on at least one prior intermediate value in the series.

15. The method of claim 12, further comprising:
providing another intermediate value in the series as another output value for another multiplication of the input value with another constant value.

16. An apparatus comprising:
means for receiving an input value for data to be processed;
means for generating a series of intermediate values based on the input value, at least one intermediate value in the series being generated based on at least one other intermediate value in the series; and
means for providing one intermediate value in the series as an output value for a multiplication of the input value with a constant value.

17. The apparatus of claim 16, wherein the means for generating the series of intermediate values comprises
means for setting a first intermediate value in the series to the input value, and
means for generating each subsequent intermediate value based on at least one prior intermediate value in the series.

18. The apparatus of claim 16, wherein the means for generating the series of intermediate values comprises
means for generating each intermediate value in the series, except for a first intermediate value in the series, by performing a bit shift, an addition, or a bit shift and an addition on at least one prior intermediate value in the series.

19. The apparatus of claim 16, further comprising:
means for providing another intermediate value in the series as another output value for another multiplication of the input value with another constant value.

20. An apparatus to obtain an output value for an operation, comprising:
a first logic to receive an input value for data to be processed;
a second logic to generate a series of intermediate values based on the input value and to generate at least one intermediate value in the series based on at least one other intermediate value in the series; and
a third logic to provide one intermediate value in the series as the output value for the operation.

21. The apparatus of claim 20, wherein the operation is a multiplication of the input value with a constant value.

22. The apparatus of claim 20, wherein the second logic sets a first intermediate value in the series to the input value and generates each subsequent intermediate value based on at least one prior intermediate value in the series, and wherein the third logic provides a last intermediate value in the series as the output value for the operation.

23. A method of obtaining an output value for an operation, comprising:
receiving an input value for data to be processed;
generating a series of intermediate values based on the input value, at least one intermediate value in the series being generated based on at least one other intermediate value in the series; and
providing one intermediate value in the series as the output value for the operation.

24. A computer-readable medium including at least one instruction stored thereon, comprising:
at least one instruction to receive an input value for data to be processed,
at least one instruction to generate a series of intermediate values based on the input value, at least one intermediate value in the series being generated based on at least one other intermediate value in the series, and
at least one instruction to provide one intermediate value in the series as an output value for an operation.

25. An apparatus comprising:
a first logic to perform processing on a set of input data values to obtain a set of output data values;
a second logic to perform multiplication of an input data value with a constant value for the processing, to generate a series of intermediate values for the multiplication, and to generate at least one intermediate value in the series based on at least one other intermediate value in the series; and
a third logic to provide one intermediate value in the series as a result of the multiplication of the input data value with the constant value.

26. The apparatus of claim 25, wherein the first logic performs the processing to transform the set of input data values from a first domain to a second domain.

27. The apparatus of claim 25, wherein the first logic performs the processing to filter the set of input data values.

28. The apparatus of claim 25, wherein the constant value is approximated with an integer value.

29. The apparatus of claim 25, wherein the constant value is approximated with a rational dyadic constant having an integer numerator and a denominator that is a power of twos.

30. A method comprising:
performing processing on a set of input data values to obtain a set of output data values;
performing multiplication of an input data value with a constant value for the processing;
generating a series of intermediate values for the multiplication, the series having at least one intermediate value generated based on at least one other intermediate value in the series; and
providing one intermediate value in the series as a result of the multiplication of the input data value with the constant value.

31. The method of claim 30, wherein the performing processing comprises
performing the processing to transform the set of input data values from a first domain to a second domain.

32. The method of claim 30, wherein the performing processing comprises
performing the processing to filter the set of input data values.

33. An apparatus comprising:
means for performing processing on a set of input data values to obtain a set of output data values;
means for performing multiplication of an input data value with a constant value for the processing;
means for generating a series of intermediate values for the multiplication, the series having at least one intermediate value generated based on at least one other intermediate value in the series; and
means for providing one intermediate value in the series as a result of the multiplication of the input data value with the constant value.

34. The apparatus of claim 33, wherein the means for performing processing comprises means for performing the processing to transform the set of input data values from a first domain to a second domain.

35. The apparatus of claim 33, wherein the means for performing processing comprises means for performing the processing to filter the set of input data values.

36. An apparatus comprising:
a first logic to perform a transform on a set of input values to obtain a set of output values;
a second logic to perform multiplication of an intermediate variable with a constant value for the transform, to generate a series of intermediate values for the multiplication, and to generate at least one intermediate value in the series based on at least one other intermediate value in the series; and
a third logic to provide one intermediate value in the series as a result of the multiplication of the intermediate variable with the constant value.

37. The apparatus of claim 36, wherein the first logic performs a discrete cosine transform (DCT) on the set of input values and to obtain a set of transform coefficients for the set of output values.

38. The apparatus of claim 36, wherein the first logic performs an inverse discrete cosine transform (IDCT) on a set of transform coefficients for the set of input values to obtain the set of output values.

39. The apparatus of claim 36, wherein the constant value is approximated with an integer value.

40. The apparatus of claim 36, wherein the constant value is approximated with a rational dyadic constant having an integer numerator and a denominator that is a power of twos.

41. A method comprising:
performing a transform on a set of input values to obtain a set of output values;
performing multiplication of an intermediate variable with a constant value for the transform;
generating a series of intermediate values for the multiplication, the series having at least one intermediate value generated based on at least one other intermediate value in the series; and
providing one intermediate value in the series as a result of the multiplication of the intermediate variable with the constant value.

42. The method of claim 41, wherein the performing a transform comprises
performing a discrete cosine transform (DCT) on the set of input values to obtain a set of transform coefficients for the set of output values.

43. The method of claim 41, wherein the performing a transform comprises
performing an inverse discrete cosine transform (IDCT) on a set of transform coefficients for the set of input values to obtain the set of output values.

44. An apparatus comprising:
means for performing a transform on a set of input values to obtain a set of output values;
means for performing multiplication of an intermediate variable with a constant value for the transform;
means for generating a series of intermediate values for the multiplication, the series having at least one intermediate value generated based on at least one other intermediate value in the series; and
means for providing one intermediate value in the series as a result of the multiplication of the intermediate variable with the constant value.

45. The apparatus of claim 44, wherein the means for performing a transform comprises means for performing a discrete cosine transform (DCT) on the set of input values to obtain a set of transform coefficients for the set of output values.

46. The apparatus of claim 44, wherein the means for performing a transform comprises means for performing an inverse discrete cosine transform (IDCT) on a set of transform coefficients for the set of input values to obtain the set of output values.

47. An apparatus comprising:
a first logic to perform a transform on eight input values to obtain eight output values;
a second logic to perform two multiplications on a first intermediate variable for the transform; and
a third logic to perform two multiplications on a second intermediate variable for the transform, the second and third logic performing four of a total of six multiplications for the transform.

48. The apparatus of claim 47, wherein the second logic generates a first series of intermediate values for the two multiplications on the first intermediate variable, and wherein the third logic generates a second series of intermediate values for the two multiplications on the second intermediate variable.

49. The apparatus of claim 48, further comprising:
a fourth logic to generate a third series of intermediate values for a multiplication on a third intermediate variable for the transform; and
a fifth logic to generate a fourth series of intermediate values for a multiplication on a fourth intermediate variable for the transform.
